(19) United States
(12) Patent Application Publication
(10) Pub. No.: US 2026/0005182 A1
(43) Pub. Date: Jan. 1, 2026

(54) POWER SEMICONDUCTOR PACKAGE AND FABRICATION METHOD THEREOF

(71) Applicant: TONG HSING ELECTRONIC INDUSTRIES, LTD., Taoyuan City (TW)

(72) Inventors: Yan-Wei Chen, Taoyuan City (TW); Chih-Jen Su, Taoyuan City (TW)

(73) Assignee: TONG HSING ELECTRONIC INDUSTRIES, LTD., Taoyuan City (TW)

(21) Appl. No.: 19/253,985

(22) Filed: Jun. 30, 2025

Related U.S. Application Data
(60) Provisional application No. 63/666,261, filed on Jul. 1, 2024.

(51) Int. Cl. H01L 23/00; H01L 21/56; H01L 23/15; H01L 23/31; H01L 23/498

(52) U.S. Cl. CPC H01L 24/29; H01L 21/561; H01L 23/15; H01L 23/3121; H01L 24/32; H01L 24/83; H01L 24/96; H01L 24/97; H01L 23/49866; H01L 24/48; H01L 24/73; H01L 2224/29082; H01L 2224/29139; H01L 2224/32058; H01L 2224/32059; H01L 2224/32227; H01L 2224/48227; H01L 2224/73265; H01L 2224/83192; H01L 2224/8384; H01L 2224/96; H01L 2224/97; H01L 2924/35121

(57) ABSTRACT

A power semiconductor package includes a substrate; a chip affixed to the substrate via a dual-layer sintered silver bonding structure; and an epoxy molding compound that at least encapsulates the chip and a portion of the dual-layer sintered silver bonding structure. The dual-layer sintered silver bonding structure includes a first sintered silver layer positioned on the substrate, and a second sintered silver layer positioned on the first sintered silver layer, with the chip located on the second sintered silver layer. The first sintered silver layer has a porosity of less than 5%, and the second sintered silver layer has a Young's modulus of less than 20 GPa.

### CROSS REFERENCE TO RELATED APPLICATIONS

This application claims the benefit of U.S. Provisional Application No. 63/666,261, filed on Jul. 1, 2024. The content of the application is incorporated herein by reference.

### BACKGROUND OF THE INVENTION

### 1. Field of the Invention

The present invention relates to the field of semiconductor technology, and more particularly to a power semiconductor package and its manufacturing method.

### 2. Description of the Prior Art

In the field of electronics manufacturing, especially for the bonding of discrete components (e.g., the process of attaching chips to a substrate), the current mainstream practice involves using high-lead solder for bonding due to its lower cost. Furthermore, the thermal conductivity of traditional high-lead solder bonding methods is approximately 45 W/m·K.

With the increasing adoption of high-power chips (e.g., GaN/SiC MOSFETs), there's a growing demand for improved heat dissipation performance. To further enhance the thermal performance of chips, it becomes necessary to consider materials with superior thermal conductivity compared to high-lead solder, which is why silver sintering technology has been proposed as an alternative.

However, when actually applied to chip bonding, existing pressureless silver sintering technology still faces some technical challenges. Its main drawback is that pressureless silver paste may exhibit cracking and delamination at certain critical interfaces, such as the interface between the silver paste and the substrate (or lead frame), or the interface between the silver paste and the chip sidewall. These interface issues directly impact product reliability.

### SUMMARY OF THE INVENTION

It is one objective of the present invention to provide an improved high-power semiconductor package and a method for manufacturing the same, so as to address the deficiencies or shortcomings of existing technologies.

One aspect of the invention provides a power semiconductor package including a substrate; a chip, wherein the chip is fixed to the substrate via a dual-layer sintered silver bonding structure; and an epoxy molding compound, at least encapsulating the chip and a portion of the dual-layer sintered silver bonding structure. The dual-layer sintered silver bonding structure comprises a first sintered silver layer, disposed on the substrate; and a second sintered silver layer, disposed on the first sintered silver layer, and the chip is disposed on the second sintered silver layer. The first sintered silver layer has a low porosity of less than 5%, and the second sintered silver layer has a low Young's modulus of less than 20 GPa.

According to some embodiments, the first sintered silver layer comprises uniform spherical particles in nanometer to sub-micron scale.

According to some embodiments, the second sintered silver layer comprises columnar or block-like distributed particles.

According to some embodiments, the Young's modulus of the second sintered silver layer is less than a Young's modulus of the first sintered silver layer.

According to some embodiments, an adhesion between the first sintered silver layer and the substrate is greater than 15 MPa.

According to some embodiments, the substrate is a ceramic substrate, and wherein the chip is a power chip.

According to some embodiments, the ceramic substrate has a plating layer, wherein the first sintered silver layer is disposed on the plating layer.

According to some embodiments, the plating layer is selected from a group consisting of copper, gold, and silver.

According to some embodiments, the first sintered silver layer is configured to resist a lateral shear force generated by a mismatch in coefficients of thermal expansion between the epoxy molding compound and the substrate.

According to some embodiments, the second sintered silver layer is configured to buffer a normal shear force resulting from a mismatch in coefficients of thermal expansion between the epoxy molding compound and the chip.

Another aspect of the invention provides a method for forming a power semiconductor package. A substrate is provided. A first silver paste is disposed on the substrate. A second silver paste is disposed on the first silver paste. A chip is mounted on the second silver paste. A sintering process is performed on the first silver paste and the second silver paste to form a dual-layer sintered silver bonding structure that fixes the chip to the substrate. The dual-layer sintered silver bonding structure comprises a first sintered silver layer and a second sintered silver layer. The chip is then encapsulated with an epoxy molding compound.

According to some embodiments, the first sintered silver layer has a low porosity of less than 5%.

According to some embodiments, the first sintered silver layer comprises uniform spherical particles in nanometer to sub-micron scale.

According to some embodiments, the second sintered silver layer comprises columnar or block-like distributed particles and has a low Young's modulus of less than 20 GPa.

According to some embodiments, the Young's modulus of the second sintered silver layer is less than a Young's modulus of the first sintered silver layer.

According to some embodiments, an adhesion between the first sintered silver layer and the substrate is greater than 15 MPa.

According to some embodiments, the chip is a power chip.

According to some embodiments, the substrate is a ceramic substrate.

According to some embodiments, the ceramic substrate has a plating layer, wherein the first sintered silver layer is disposed on the plating layer.

According to some embodiments, the plating layer is selected from a group consisting of copper, gold, and silver.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 are schematic diagrams illustrating a method for fabricating a power semiconductor package according to an embodiment of the present invention.

### DETAILED DESCRIPTION

The following is a specific example to illustrate the implementation of the “power semiconductor package and a fabrication method thereof” disclosed in the present invention. Those skilled in the art can understand the advantages and effects of the present invention from the content disclosed in this specification. The present invention can be implemented or applied through other different specific embodiments, and various details in this specification can also be modified and changed based on different viewpoints and applications without departing from the concept of the present invention. In addition, the drawings of the present invention are only simple schematic illustrations and are not depictions based on actual dimensions, as is stated in advance. The following embodiments will further describe the relevant technical content of the present invention in detail, but the disclosed content is not intended to limit the scope of the present invention.

It should be understood that although terms such as “first”, “second” and “third” may be used herein to describe various elements or signals, these elements or signals should not be limited by these terms. These terms are primarily used to distinguish one component from another component or one signal from another signal. In addition, the term “or” used in this article shall include any one or combination of more of the associated listed items depending on the actual situation.

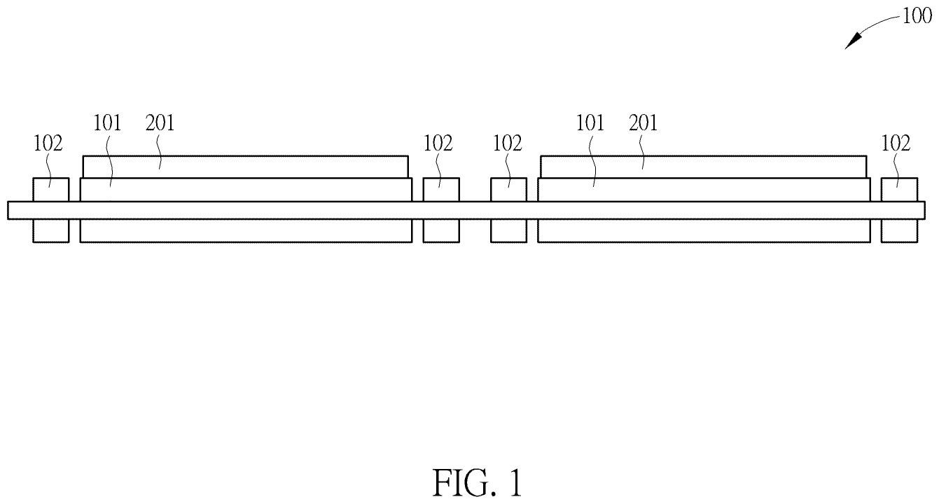

Please refer to FIGS. 1 to 7, which are schematic diagrams illustrating a method for fabricating a power semiconductor package according to an embodiment of the present invention. As shown in FIG. 1, first, a substrate 100 is provided. For example, the substrate may comprise a ceramic substrate. According to embodiments of the present invention, the ceramic substrate, for example, includes, but is not limited to, a direct plated copper (DPC) ceramic substrate, a direct bonded copper (DBC) ceramic substrate, or an active metal brazing (AMB) ceramic substrate. According to another embodiment of the present invention, the substrate 100 can be a leadframe.

According to an embodiment of the present invention, the substrate 100 may include at least one first plating layer 101 and at least one second plating layer 102. According to embodiments of the present invention, for example, the first plating layer 101 can be selected from the group consisting of copper, gold, and silver, but is not limited thereto. According to embodiments of the present invention, for example, the second plating layer 102 can be selected from the group consisting of copper, gold, and silver, but is not limited thereto.

Next, a dispensing process is performed to apply a first silver paste 201 onto the first plating layer 101. According to an embodiment of the present invention, the first silver paste 201 can be a pressureless sintering silver paste, which needs to satisfy the following three requirements: (1) minute and uniform particles; (2) low porosity; and (3) free of columnar or blocky silver particles. According to an embodiment of the present invention, for example, the first silver paste 201 comprises uniform spherical particles of nano- to submicron-grade. According to an embodiment of the present invention, for example, the first silver paste 201 has a low porosity of less than 5%. Subsequently, a baking process may optionally be performed on the first silver paste 201 to achieve a semi-cured state.

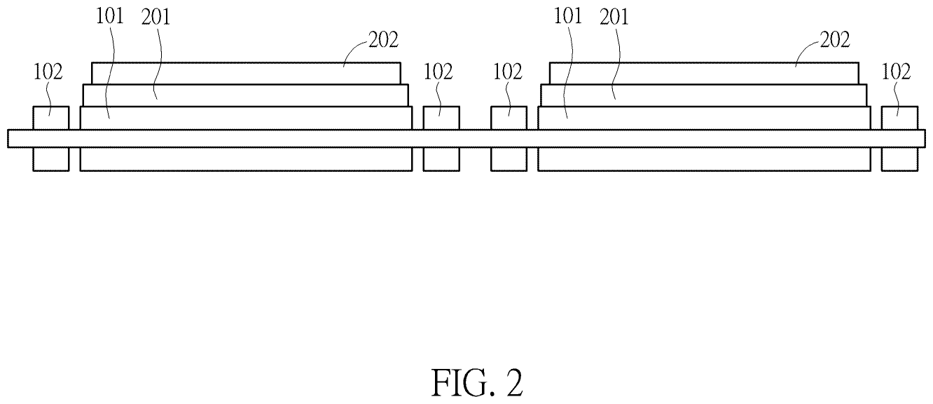

As shown in FIG. 2, an epoxy dispensing process is then performed again to apply a second silver paste 202 on the first silver paste 201. According to an embodiment of the present invention, the applied area of the second silver paste 202 can be less than or equal to the top surface area of the first silver paste 201. According to an embodiment of the present invention, the first silver paste 201 can be a pressureless sintered silver paste, which needs to satisfy the following two requirements: (1) containing columnar or block-shaped silver particles; and (2) having a Young's modulus of less than 20 GPa after sintering.

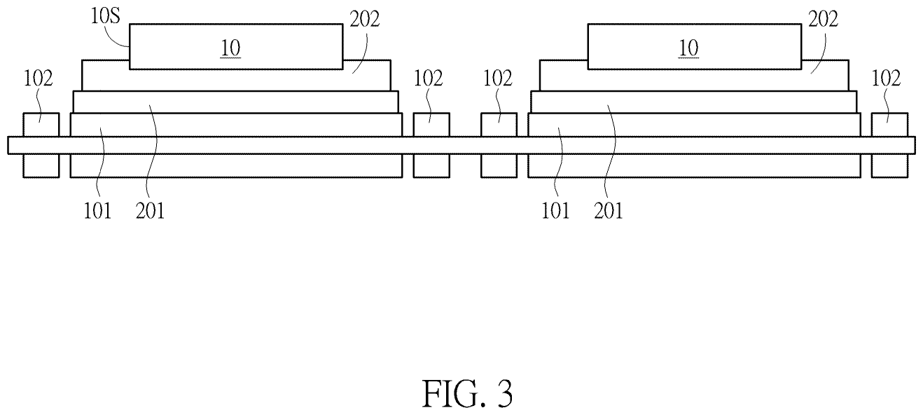

As shown in FIG. 3, a chip 10 is then placed on the second silver paste 202. According to an embodiment of the present invention, the chip 10 is, for example, a power chip. According to an embodiment of the present invention, the chip 10 is a high-power chip, for example, comprising a Gallium Nitride Metal Oxide Semiconductor Field-Effect Transistor (GaN MOSFET) or a Silicon Carbide Metal Oxide Semiconductor Field-Effect Transistor (SiC MOSFET). According to an embodiment of the present invention, the second silver paste 202 is in direct contact with the sidewall 10S of the chip 10. According to an embodiment of the present invention, the chip 10 does not directly contact the first silver paste 201.

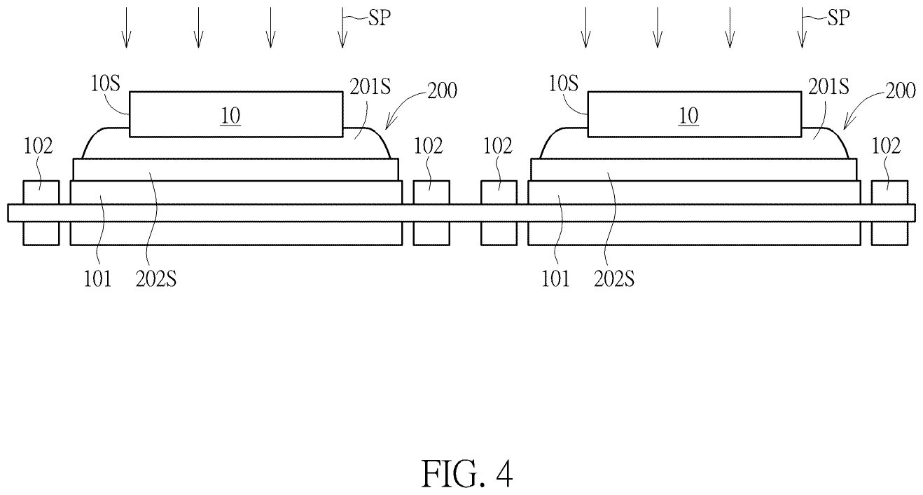

Then, as shown in FIG. 4, a sintering process SP is performed on the stacked structure in FIG. 3, so that the first silver paste 201 and the second silver paste 202 are sintered to form a dual-layer sintered silver bonding structure 200 that fixes the chip 10 to the substrate 100. According to an embodiment of the present invention, the dual-layer sintered silver bonding structure 200 includes a first sintered silver layer 201S and a second sintered silver layer 202S. According to an embodiment of the present invention, the chip 10 does not directly contact the first sintered silver layer 201S.

According to an embodiment of the present invention, the first sintered silver layer 201S comprises uniformly spherical particles ranging from nanoscale to submicron scale, and has a low porosity of less than 5%. According to an embodiment of the present invention, the second sintered silver paste layer 202S comprises columnar or block-shaped particles distributed from nanoscale to micron scale, and its Young's modulus is, for example, less than 20 GPa. According to an embodiment of the present invention, the Young's modulus of the second sintered silver layer 202S is less than the Young's modulus of the first sintered silver layer 201S. According to an embodiment of the present invention, the adhesion between the first sintered silver layer 201S and the substrate 100 is greater than 15 MPa.

According to an embodiment of the present invention, the silver content of the first sintered silver layer 201S is, for example, about 91-93 wt %, and the silver content of the second sintered silver paste layer 202S is, for example, about 85-90 wt %. According to an embodiment of the present invention, the coefficient of thermal expansion of the first sintered silver layer 201S is, for example, about 20-25 PPM/° C., and the coefficient of thermal expansion of the second sintered silver paste layer 202S is, for example, about 26-40 PPM/° C. According to an embodiment of the present invention, the Young's modulus of the first sintered silver layer 201S is, for example, about 17.5-21 GPa, and the Young's modulus of the second sintered silver paste layer 202S is, for example, about 8-17.5 GPa. According to an embodiment of the present invention, the porosity of the first sintered silver layer 201S is, for example, less than 5%, and the porosity of the second sintered silver paste layer 202S is, for example, 10-20%.

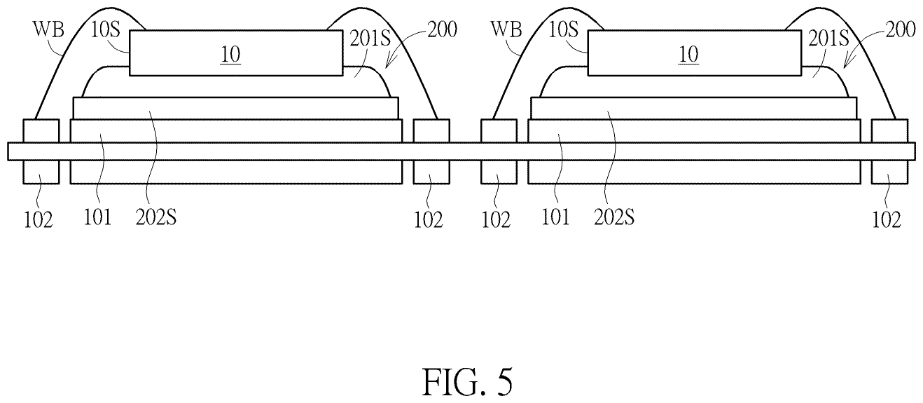

As shown in FIG. 5, a wire bonding process is then performed, utilizing bonding wires WB to electrically connect the chip 10 to the second plating layer 102. According to an embodiment of the present invention, the bonding wires WB may comprise copper or gold, but are not limited thereto.

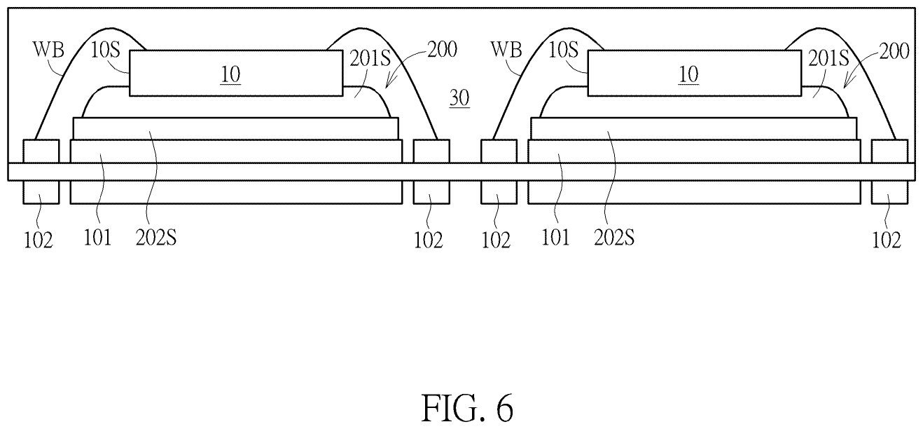

As shown in FIG. 6, a molding process is then performed to form an epoxy molding compound (EMC) 30, which at least encapsulates the chip 10, the bonding wires WB, and a portion of the dual-layer sintered silver bonding structure 200. According to an embodiment of the present invention, the epoxy molding compound 30 directly contacts the sidewall 10S of the chip 10, the first sintered silver layer 201S, and the second sintered silver layer 202S.

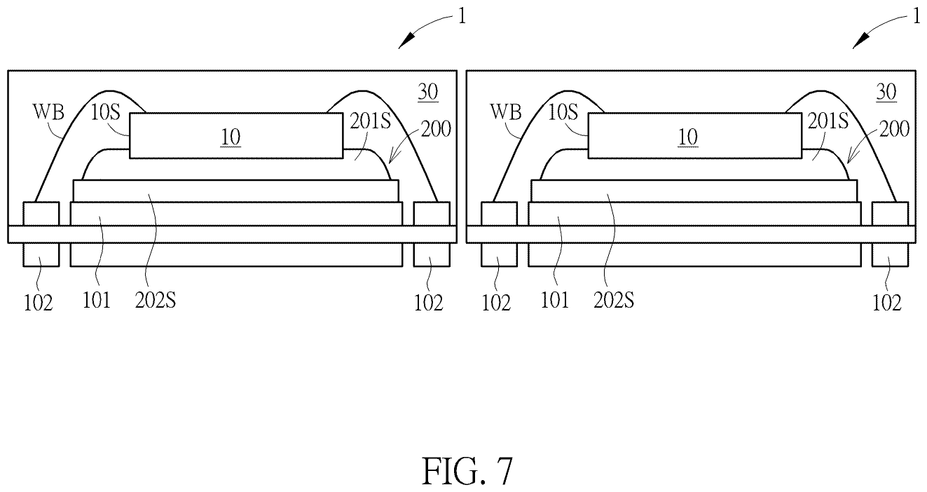

Finally, as shown in FIG. 7, post-packaging dicing, such as mechanical cutting or laser cutting, is performed to form a plurality of power semiconductor packages 1. According to an embodiment of the present invention, the first sintered silver layer 201S is composed of nano- to sub-micron uniformly spherical particle silver paste with a dense and continuous structure and low porosity. Its adhesion to the substrate 100 is greater than 15 MPa, enabling it to resist the lateral shear forces generated by the coefficient of thermal expansion (CTE) mismatch between the first plating layer 101 and the epoxy molding compound 30, thereby preventing cracking at the interface between the first sintered silver layer 201S and the substrate 100. The second sintered silver layer 202S possesses a low modulus and its silver paste particles are blocky and columnar, thus allowing it to buffer the normal shear forces caused by the CTE mismatch between the epoxy molding compound 30 and the chip 10. Furthermore, if conventional nano-scale spherical sintered silver paste were used as the material connecting the chip 10, cracking might occur at the interface between the sintered silver paste and the sidewall of the chip 10. In a preferred embodiment of the present invention, a second sintered silver layer 202S comprising columnar or blocky distributed particles of nano- to micron-scale is used as the material connecting the chip 10. Due to the columnar or blocky distribution of the silver paste particles in the second sintered silver layer 202S and its lower Young's modulus, it can prevent crevice propagation when crevices begin to occur in the second sintered silver layer 202S, thereby avoiding cracking at the interface between the second sintered silver layer 202S and the chip 10.

The present invention combines two types of pressureless silver pastes with different characteristics, solving the problem of potential cracking at different locations within power semiconductor packages. The advantages of the present invention include maintaining high heat dissipation performance, reducing the possibility of cracking between the silver paste and the chip sidewall, and preserving the high reliability and performance of the power semiconductor package

Structurally, as shown in FIG. 7, the power semiconductor package 1 of the present invention comprises a substrate 100 and a chip 10, which is fixed to the substrate 100 via a dual-layer sintered silver bonding structure 200. According to an embodiment of the present invention, the chip is a power chip. According to an embodiment of the present invention, the substrate 100 for example includes a ceramic substrate, but is not limited thereto. According to an embodiment of the present invention, the ceramic substrate has a first plating layer 101, wherein a first sintered silver layer 201S is disposed on the first plating layer 101. According to an embodiment of the present invention, the first plating layer 101 is selected from the group consisting of copper, gold, and silver.

According to an embodiment of the present invention, the power semiconductor package 1 further includes an epoxy molding compound 30 encapsulating the chip 10 and a portion of the dual-layer sintered silver bonding structure 200. According to an embodiment of the present invention, the dual-layer sintered silver bonding structure 200 comprises a first sintered silver layer 201S, disposed on the substrate 100; and a second sintered silver layer 202S, disposed on the first sintered silver layer 201S.

According to an embodiment of the present invention, the chip 10 is fixed on the second sintered silver layer 202S, and the chip 10 does not directly contact the first sintered silver layer 201S.

According to an embodiment of the present invention, the first sintered silver layer 201S has a low porosity of less than 5%, and the second sintered silver layer 202S has a low Young's modulus of less than 20 GPa. According to an embodiment of the present invention, the Young's modulus of the second sintered silver layer 202S is less than the Young's modulus of the first sintered silver layer 201S.

According to an embodiment of the present invention, the first sintered silver layer 201S has uniform spherical particles in nanometer to sub-micron scale. According to an embodiment of the present invention, the second sintered silver layer 202S has columnar or block-like distributed particles.

According to an embodiment of the present invention, the adhesion between the first sintered silver layer 201S and the substrate 100 is greater than 15 MPa.

According to an embodiment of the present invention, the first sintered silver layer 201S is used to resist lateral shear forces generated by the mismatch of coefficients of thermal expansion between the epoxy molding compound 30 and the substrate 100.

According to an embodiment of the present invention, the second sintered silver layer 202S is used to buffer the normal shear forces caused by the mismatch of coefficients of thermal expansion between the epoxy molding compound 30 and the chip 10.

According to an embodiment of the present invention, when cracks begin to appear, the second sintered silver layer 202S is used to prevent crack propagation.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power semiconductor package, comprising:
a substrate;
a chip, wherein the chip is fixed to the substrate via a dual-layer sintered silver bonding structure; and
an epoxy molding compound, at least encapsulating the chip and a portion of the dual-layer sintered silver bonding structure;
wherein the dual-layer sintered silver bonding structure comprises a first sintered silver layer, disposed on the substrate; and a second sintered silver layer, disposed on the first sintered silver layer, and the chip is disposed on the second sintered silver layer;
wherein the first sintered silver layer has a low porosity of less than 5%, and the second sintered silver layer has a low Young's modulus of less than 20 GPa.

2. The power semiconductor package according to claim 1, wherein the first sintered silver layer comprises uniform spherical particles in nanometer to sub-micron scale.

3. The power semiconductor package according to claim 1, wherein the second sintered silver layer comprises columnar or block-like distributed particles.

4. The power semiconductor package according to claim 1, wherein the Young's modulus of the second sintered silver layer is less than a Young's modulus of the first sintered silver layer.

5. The power semiconductor package according to claim 1, wherein an adhesion between the first sintered silver layer and the substrate is greater than 15 MPa.

6. The power semiconductor package according to claim 1, wherein the substrate is a ceramic substrate, and wherein the chip is a power chip.

7. The power semiconductor package according to claim 6, wherein the ceramic substrate has a plating layer, wherein the first sintered silver layer is disposed on the plating layer.

8. The power semiconductor package according to claim 7, wherein the plating layer is selected from a group consisting of copper, gold, and silver.

9. The power semiconductor package according to claim 1, wherein the first sintered silver layer is configured to resist a lateral shear force generated by a mismatch in coefficients of thermal expansion between the epoxy molding compound and the substrate.

10. The power semiconductor package according to claim 1, wherein the second sintered silver layer is configured to buffer a normal shear force resulting from a mismatch in coefficients of thermal expansion between the epoxy molding compound and the chip.

11. A method for forming a power semiconductor package, comprising:
providing a substrate;
applying a first silver paste on the substrate;
applying a second silver paste on the first silver paste;
disposing a chip on the second silver paste;
performing a sintering process on the first silver paste and the second silver paste to form a dual-layer sintered silver bonding structure that fixes the chip to the substrate, wherein the dual-layer sintered silver bonding structure comprises a first sintered silver layer and a second sintered silver layer; and
encapsulating the chip with an epoxy molding compound.

12. The method according to claim 11, wherein the first sintered silver layer has a low porosity of less than 5%.

13. The method according to claim 11, wherein the first sintered silver layer comprises uniform spherical particles in nanometer to sub-micron scale.

14. The method according to claim 11, wherein the second sintered silver layer comprises columnar or block-like distributed particles and has a low Young's modulus of less than 20 GPa.

15. The method according to claim 14, wherein the Young's modulus of the second sintered silver layer is less than a Young's modulus of the first sintered silver layer.

16. The method according to claim 11, wherein an adhesion between the first sintered silver layer and the substrate is greater than 15 MPa.

17. The method according to claim 11, wherein the chip is a power chip.

18. The method according to claim 11, wherein the substrate is a ceramic substrate.

19. The method according to claim 18, wherein the ceramic substrate has a plating layer, wherein the first sintered silver layer is disposed on the plating layer.

20. The method according to claim 19, wherein the plating layer is selected from a group consisting of copper, gold, and silver.
